(19) United States
(12) Patent Application Publication
(10) Pub. No.: US 2009/0029549 A1
(43) Pub. Date: Jan. 29, 2009

(54) METHOD OF SILICIDE FORMATION FOR NANO STRUCTURES

(76) Inventors: Oh-Jung Kwon, Hopewell Junction, NY (US); Robert J. Purtell, Mohegan Lake, NY (US); Viraj Y. Sardesai, Poughkeepsie, NY (US)

Correspondence Address: FREDERICK W. GIBB, III;Gibb Intellectual Property Law Firm, LLC, 2568-A RIVA ROAD, SUITE 304, ANNAPOLIS, MD, 21401, US

(21) Appl. No.: 11/781,599

(22) Filed: Jul. 23, 2007

(51) Int. Cl. H01L 21/44

(52) U.S. Cl. 438/682; 257/E21.593

(57) ABSTRACT

A method forms a first layer over a second layer that comprises silicon. A mask is formed and patterned over the insulator layer. Then, a heavy inert gas such as Xenon (Xe) is implanted through the openings in the mask, through the insulator layer, and into the regions of the silicon layer that are below the opening in the mask. The portions of the insulator layer that are below the openings in the mask are etched away and the mask is removed. A metal or metal alloy layer is formed over the first layer and the exposed regions of the second layer. At least the second layer is heated in a silicide process such that the metal and the exposed regions of the second layer combine to form silicide regions. After this, any remaining metal material can be removed to remove to leave the silicide regions adjacent non-silicide regions of the second layer.

### BACKGROUND AND SUMMARY

The embodiments of the invention generally relate to the formation of silicide regions and more particularly to a method that implants Xenon into the silicon substrate before the silicide formation process to eliminate the formation of Nickel disilicide (NiSi₂) pipes in the silicide regions.

Uncontrolled nickel silicide formation results in Nickel disilicide (NiSi₂) pipes (tubes of NiSi₂ material). The NiSi₂ pipes are a major yield detractor for nano range semiconductor technologies. One proposed solution to avoid NiSi₂ formation is to add Pt to the Nickel to form NiPtSi; however, this process has not successfully controlled the formation of NiSi₂ pipes.

Another option for eliminating NiSi₂ pipes that has been explored incorporates Nitrogen in the film (see U.S. Pat. No. 5,705,441, which is incorporated herein by reference). In this process, nitrogen is supposed to provide nucleation centers and limit grain growth of the silicide. However, Nitrogen forms a nitride film and as the silicide thickness reduces, this can increase silicide resistance.

Similarly incorporation of fluorine is another option that was attempted in U.S. Pat. No. 6,255,179 (incorporated herein by reference). However both F and N have small atomic sizes and can diffuse with thermal processing. Also N can be incorporated during any NiPt metal deposition and may diffuse into areas where there is no silicide.

In view of the foregoing, this disclosure presents a method of providing a Xe implant thru a patterned mask. Xenon has larger atomic size than fluorine or nitrogen and therefore acts as a NiSi₂ barrier. Further, Xenon is inert and therefore does not form any compounds. Implanting Xe thru an insulator or resist mask implants Xe only where silicide is formed and does not cause the Xe to change the stress of other films.

Therefore, the embodiments herein provide a method that forms a first layer, such as an insulator layer over a second layer that comprises silicon. A mask is formed and patterned over the insulator layer. Then, a heavy inert gas such as Xenon (Xe) is implanted through the openings in the mask, through the insulator layer, and into the regions of the silicon layer that are below the opening in the mask (e.g., source and drain regions). This creates an implanted region in the second layer below the openings in the mask.

The portions of the insulator layer that are below the openings in the mask are etched away and the mask is removed. This etching process is performed in a manner such that exposed regions of the silicon substrate layer are left uncovered by the insulator layer. For example, the insulator layer could have openings leaving source and drain regions exposed in a silicon substrate.

Then, the traditional silicide or salacide process can be performed by forming a metal or metal alloy layer over the first (e.g., insulator) layer and the exposed source and drain regions of the second layer. The silicide process continues by performing heating of at least the second layer in a manner such that the metal and the exposed source and drain regions of the second layer combine to form silicide regions in upper portions of the source and drain regions. After this, any remaining metal material can be removed to leave the silicide regions adjacent non-silicide regions of the second layer.

The above-described implanting process implants the Xenon in sufficient quantities and at sufficient depths so as to prevent formation of NiSi₂ in the silicide regions during the heating. For example, the implanting of the Xenon can comprise implanting the Xenon in a dosage less than 5E14 and at a power less than 30 KeV.

These and other aspects of the embodiments of the invention will be better appreciated and understood when considered in conjunction with the following description and the accompanying drawings. It should be understood, however, that the following descriptions, while indicating embodiments of the invention and numerous specific details thereof, are given by way of illustration and not of limitation. Many changes and modifications may be made within the scope of the embodiments of the invention without departing from the spirit thereof, and the embodiments of the invention include all such modifications.

### BRIEF DESCRIPTION OF THE DRAWINGS

The embodiments of the invention will be better understood from the following detailed description with reference to the drawings, in which:

FIG. 1 is a schematic diagram illustrating a method embodiment of the invention;

FIG. 2 is a schematic diagram illustrating a method embodiment of the invention; and

FIG. 3 is a schematic diagram illustrating a method embodiment of the invention.

### DETAILED DESCRIPTION OF EMBODIMENTS

The embodiments of the invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the embodiments of the invention. The examples used herein are intended merely to facilitate an understanding of ways in which the embodiments of the invention may be practiced and to further enable those of skill in the art to practice the embodiments of the invention. Accordingly, the examples should not be construed as limiting the scope of the embodiments of the invention.

As mentioned above, uncontrolled nickel silicide formation results in Nickel disilicide (NiSi₂) pipes (tubes of NiSi₂ material), which are a major yield detractor for nano range semiconductor technologies. In view of this problem, this disclosure presents a method of providing a Xe implant through a patterned insulator.

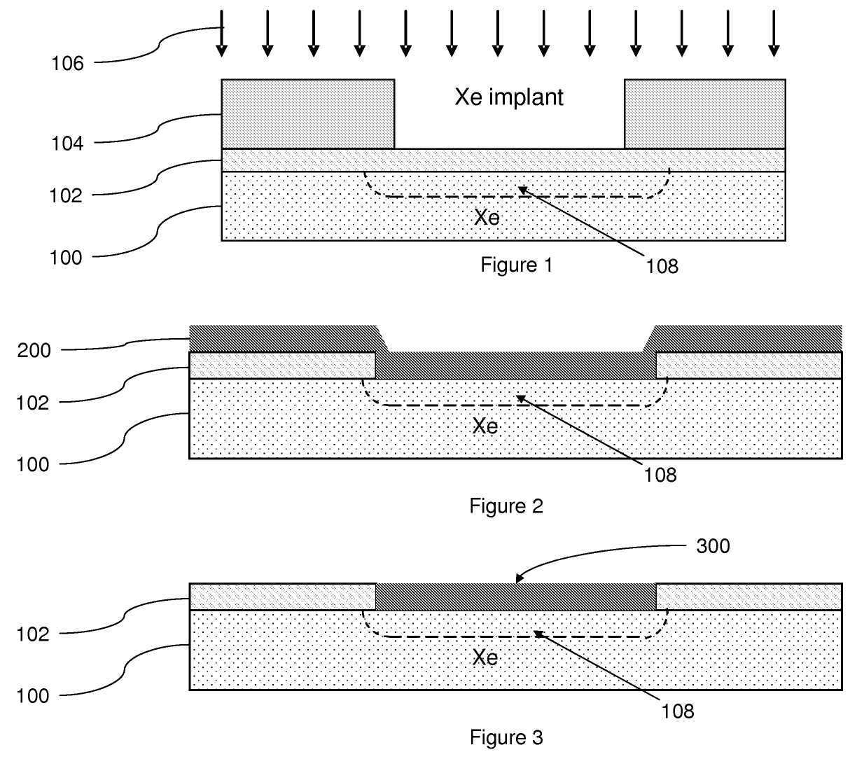

As shown in FIG. 1, an insulator layer 102 is deposited on a silicon semiconductor substrate 100. A mask 104 is formed and patterned to define areas where self-aligned silicide (silicide) will be formed. Xenon is implanted 106 through the mask 104 to form the implant 108.

Then, as shown in FIG. 2, the pattern of the mask 104 is etched into the insulator layer 102, and the resist 104 is stripped. Next, a metal or metal alloy 200 such as nickel or Nickel-platinum is deposited. Areas where the metal 200 contacts the silicon substrate 100 are converted to silicides 300 by annealing (heating) as shown in FIG. 3. Further, after stripping off the mask 104 any unreacted metal/alloy 200 on top of the insulator 102 areas an additional transformation anneal can be performed to convert the salicide into a stable silicide phase. Due to the Xe implant 108, formation of NiSi2 is inhibited.

While the foregoing examples show the invention as being used with source/drains and/or an insulator over a substrate, as would be understood by those ordinarily skilled in the art, the embodiments herein can be used without the insulator layer. Thus, the Xe could be implanted into the semiconductor as a shallower implant. Xenon can also be blanket implanted through insulator if non-salicide areas are blocked by other layers without using of mask.

Therefore, the embodiments herein provide a method that forms a first layer 102, such as an insulator layer over a second layer 100 that comprises silicon. A mask 104 is formed and patterned over the insulator layer 102. Then, a heavy inert gas 106 such as Xenon (Xe) is implanted through the openings in the mask 104, through the insulator layer 102, and into the regions of the silicon layer 100 that are below the openings in the mask 104 (e.g., source and drain regions). This creates the implanted region 108 in the second layer 100 below the openings in the mask 104.

The portions of the insulator layer 102 that are below the openings in the mask 104 are etched away and the mask 104 is removed. This etching process is performed in a manner such that exposed regions of the silicon substrate layer 100 are left uncovered by the insulator layer 102. For example, the insulator layer 102 could have openings leaving source and drain regions exposed in the silicon substrate 100.

Then, the traditional silicide or salacide process can be performed by forming a metal or metal alloy layer 200 over the first (e.g., insulator) layer 102 and the exposed source and drain regions of the second layer 100. The silicide process continues by performing heating of at least the second layer 100 in a manner such that the metal 200 and the exposed source and drain regions of the second layer 100 combine to form silicide regions 300 in upper portions of the substrate 100 (e.g., upper portions of the source and drain regions). After this, any remaining metal material 200 can be removed to leave the silicide regions 300 adjacent non-silicide regions of the second layer 100.

The above-described implanting process 106 implants the Xenon in sufficient quantities and at sufficient depths so as to prevent formation of NiSi₂ in the silicide regions during the heating. For example, the implanting of the Xenon can comprise implanting the Xenon in a dosage less than 5E14 and at a power less than 30 KeV.

While some conventional processes have mentioned the use of Xenon, they do so in a two step metal deposition where a first layer of Ni is deposited with Xe and then a second layer of Ni is deposited with Ar (see U.S. Pat. No. 6,689,687 which is incorporated herein by reference). Thus, while Xenon is mentioned is other processes, such conventional processes can result in placing N, F, or Xe within the insulating layers, which can cause leakage.

To the contrary, the present invention produces various advantages because the Xenon amorphizes the silicon surface. Thus, the inventive process results in more uniform silicide formation and will not result in spike defects due to faster growth along crystallographic planes. The Xenon implant barrier created by this inventive process prevents NiSi₂ formation without affecting stress or incorporating Xenon in unsilicided areas.

The Xenon implant also can help forming uniform NiSi. It eliminates co-existence of metal rich phases such as Ni2Si, Ni3Si2 etc. The nickel in metal rich phases tends to get etched out in subsequent wet etching process resulting in non uniform grainy appearance. Therefore the Xenon implant results in smooth, uniform silicide.

The foregoing description of the specific embodiments will so fully reveal the general nature of the invention that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments of the invention have been described in terms of embodiments, those skilled in the art will recognize that the embodiments of the invention can be practiced with modification within the spirit and scope of the appended claims.

What is claimed is:

1. A method comprising:
forming a first layer over a second layer comprising silicon;
patterning a mask having openings over said first layer;
implanting Xenon through said openings, through said first layer, and into said second layer in regions below said openings;
removing portions of said first layer below said openings to leave exposed regions of said second layer;
removing said mask;
forming a metal over said first layer and said exposed regions of said second layer;
heating said second layer in a manner such that said metal and said exposed regions of said second layer combine into silicide regions; and
removing remaining portions of said metal to leave said silicide regions adjacent non-silicide regions of said second layer.

2. The method according to claim 1, wherein said implanting of said Xenon implants said Xenon in sufficient quantities and at sufficient depths so as to prevent formation of Nickel disilicidein said silicide regions during said heating.

3. The method according to claim 1, wherein said implanting of said Xenon comprises implanting said Xenon in a dosage less than 5E14 and at a power less than 30 KeV.

4. A method comprising:
forming a insulator layer over a silicon substrate;
patterning a source/drain mask having openings over said insulator layer;
implanting Xenon through said openings, through said insulator layer, and into said silicon substrate in regions below said openings;
removing portions of said insulator layer below said openings to leave source/drain regions of said silicon substrate;
removing said source/drain mask;
forming a metal over said insulator layer and said exposed regions of said silicon substrate;
heating said silicon substrate in a manner such that said metal and said exposed regions of said silicon substrate combine into silicide source/drain regions; and
removing remaining portions of said metal to leave said silicide source/drain regions adjacent non-silicide regions of said silicon substrate.

5. The method according to claim 4, wherein said implanting of said Xenon implants said Xenon in sufficient quantities and at sufficient depths so as to prevent formation of NiSi₂ in said silicide source/drain regions during said heating.

6. The method according to claim 4, wherein said implanting of said Xenon comprises implanting said Xenon in a dosage less than 5E14 and at a power less than 30 KeV.
